(19) United States
(12) Patent Application Publication
(10) Pub. No.: US 2025/0244368 A1
(43) Pub. Date: Jul. 31, 2025

(54) DATA-DRIVEN GENERATOR ELECTROMAGNETIC INTERFERENCE SIGNATURE BASELINE LIBRARIES

(71) Applicant: Inventus Holdings, LLC, Juno Beach, FL (US)

(72) Inventors: Chen WANG, Jupiter, FL (US); Gabriel VELASQUEZ, Juno Beach, FL (US); Kiran SINGH, Juno Beach, FL (US); Gary C. GRIFFITH, Jupiter, FL (US)

(21) Appl. No.: 18/428,585

(22) Filed: Jan. 31, 2024

(51) Int. Cl. G01R 21/133; G01R 13/02

(52) U.S. Cl. CPC G01R 21/133; G01R 13/02

(57) ABSTRACT

A system and method of monitoring equipment performance and predicting failures and required maintenance. One aspect of the present invention uses historical generator electro magnet interference (EMI) signature data and their corresponding generator operational modes (out-of-service and active power output) to generate a baseline library for each generator in the fleet. In this library, each baseline signature is the statistical leverage of all the historical EMI signatures when the generator outputs a certain amount of active power and when the generator is out-of-service. A normality zone associated with each baseline is also provided using the statistical distribution of each data point on the signature curve. So that engineers can use the most suitable baseline when identifying abnormality given certain generator output. The correspondence between EMI signature patterns and generator operational modes is also proved and demonstrated using real-world data.

### FIELD OF THE DISCLOSURE

The present disclosure generally relates to monitoring electrical equipment in power stations and, more particularly to monitoring electrical generators.

### BACKGROUND

Consumer demand for reliable electricity continues to grow as more and more devices require electrical power. Utilities continue to invest in electrical outage prevention technologies. Electrical outage prevention technologies are distributed throughout the grid. Examples of electrical outage prevention technologies include:
Predictive Diagnostic Software helps us quickly detect deviations from normal operations and launch actions to minimize their impact.
Phasor Measurement Units at substations help identify stress points on the grid and restore service more quickly after outages.
Line Protection and Control Systems allow for the remote assessment of equipment operating conditions and help enable remote power restoration.
Digital Disturbance Recorders at electrical substations capture detailed information on system disturbances for analysis and correction.
Feeder Breaker and Regulator Intelligent Devices help utilities identify fault locations and improve power quality by providing operators in utility control centers with remote access to regulator control panels.

Monitoring devices and systems track the operation of equipment and machinery in the electrical grid. The monitoring devices and systems can be used to determine the status of the equipment and machinery and to predict the possibility of failure.

If one or more pieces of equipment or machinery fail, the operation of the portions of entire electrical grid can suffer.

### SUMMARY OF THE INVENTION

Disclosed is an improved method and system of gathering and analyzing data from AC machines. More specifically, in one example, the computer-implemented method for detecting an abnormality on an alternating current (AC) machine. The method begins with coupling at least one radio frequency current transformer to one of a ground or a neutral line of an AC machine. Next, a loop is performed, which includes iteratively performing through a series of electrical power operational modes of the AC machine, each of i) receiving a measurement of electromagnetic interference (EMI) data from the at least one radio frequency current transformer over a series of time intervals; ii) receiving a measurement of power data from the AC machine over the series of time intervals to produce a historic set of EMI data and power data over the series of time intervals; iii) identifying the power data associated with each EMI signature data; iv) using this power data to cluster the EMI signature data (for example, all EMI signature associated with 190-210 MW power data are collected into one cluster); v) for each EMI signature data cluster, calculate the mean value and statistical deviation value; and vii) storing over the series of time intervals each of i) the historic set of EMI data and power information data, ii) the mean value, and iii) the statistical deviation value, thereby establishing the AC machine's baseline data in a baseline library for normal operations.

In one example, the electrical power operational modes are measured in watts output. The alternating current (AC) machine is a generator or a transformer. The EMI data is measured in microVolts and hertz, and power information data is measured in watts.

In another example, for each generator unit and associated device, the process includes accessing recent EMI data from a radio frequency current transformer from the AC machine and the corresponding measured associated electrical power operational mode. In one example, the same AC machine is used to create the baseline library, which is being examined for abnormalities. In another example, different machines, typically the same model, are used. In this example, one AC machine is used to create the baseline library, and another AC machine is examined for abnormalities. The corresponding measured associated power operational mode is used to select a suitable baseline and associated normality zone from the AC machine's baseline data from the baseline library, each baseline in these libraries is acquired with a historic set of EMI data for the corresponding power operational mode. The recent EMI data is compared to the baseline data from the baseline library and normality zone. The abnormality is classified using an abnormality score.

In another example, the abnormality score is calculated based on a ratio between i) an area of the normality zone defined by the standard deviation for the historic set of EMI data and power data over the series of time intervals and ii) a sum or areas of the recent set of EMI data and power data that is above an upper limit of the normality zone. The abnormality is classified using the abnormality score.

The frequency range in which the settable upper limit is exceeded is used to classify a possible abnormality. For example, in response to the settable upper limit being exceeded in a 30 kHz to 500 kHz range, a notification is sent that the abnormality is at an exciter system of a generator. In response to the settable upper limit being exceeded in a 500 kHz to 5 MHz range, a notification is sent that the abnormality is at a stator groundwall insulation and/or stator slots of a generator. In response to the settable upper limit being exceeded in a 5 MHz to 30 MHz range, a notification is sent that the abnormality is at an end winding region of a generator. In response to the settable upper limit being exceeded in a 30 MHz to 100 MHz range, a notification is sent that the abnormality is at a high voltage connection to a bus system of a generator.

As a still further example, the two-axis graph for one or more of the electrical power operational modes is displayed over a series of time intervals, each of i) the set of EMI data and power information data, ii) the mean value, and iii) the standard deviation. Each of the electrical power operational modes may be displayed in different colors, a y-axis is watts, an x-axis is frequency, and the standard deviation is displayed as a shaded region.

Other features and advantages of the invention will become apparent to those skilled in the art upon review of the following detailed description, claims, and drawings.

### BRIEF DESCRIPTION OF THE DRAWINGS

The accompanying figures, where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates a high-level example of a power grid distributed system, according to the prior art;

FIG. 2 illustrates a high-level example of an electrical steam-powered generator using newer natural gas combined-cycle technology with a radio frequency current transformer, according to an example;

FIG. 3 is a high-level flow chart of the overall process of training the baseline libraries for devices in the generation fleet, according to an example;

FIG. 4 is a graph illustrating the EMI signature data baselines at various electrical power operating modes of the AC machine, according to an example;

FIG. 5 is a graph illustrating the application of the baseline library acquired from FIG. 3 to real-time EMI signature from one device, evaluating its abnormality score using normality zone as a part of the baseline associated with the same operation modes with the real-time data, according to an example;

FIG. 6 is a graph illustrating two EMI signatures, with one of the signatures capture during normal operation as the baseline and a second of signatures captured during an abnormality, according to an example;

FIG. 7 is an image taken of the AC machine with a burnt conductor for the graph in FIG. 6, according to an example;

FIG. 8 is an image taken of the AC machine after the burnt conductor of FIG. 8 is replaced, according to an example;

FIG. 9 is a graph illustrating the EMI signature data of a normal operation of FIG. 8 after the burnt conductor is replaced at one operating mode of the AC machine, according to an example;

FIG. 10 is a graph illustrating the baseline EMI signature data at one operating mode when applying the single baseline from the library to real-time EMI signature data with the calculated mean, median, and 3 sigma standard deviation that defines the normality zone associated with each baseline in the library, according to an example;

FIG. 11 is a flow chart of identifying an abnormality using historic baseline and normality zone against recent EMI signature data, according to one example; and

FIG. 12 illustrates a block diagram illustrating a processor for carrying out the flow and presenting the images of FIG. 3 through FIG. 11, according to an example.

### DETAILED DESCRIPTION

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting, but merely as a basis for the claims and as a representative basis for teaching one skilled in the art to variously employ the disclosed subject matter in virtually any appropriately detailed structure and function. Further, the terms and phrases used herein are not intended to be limiting, but rather to provide an understandable description.

### Non-Limiting Definitions

The terms “a” or “an”, as used herein, are defined as one or more than one. The term plurality, as used herein, is defined as two or more than two.

The term “adapted to” describes the hardware, software, or a combination of hardware and software that is capable of, able to accommodate, to make, or that is suitable to carry out a given function.

The term “another”, as used herein, is defined as at least a second or more.

The term “class” or “classifier” or “label” is a class label applied to data input in a machine learning algorithm.

The term “configured to” describes hardware, software or a combination of hardware and software that is adapted to, set up, arranged, built, composed, constructed, designed, or that has any combination of these characteristics to carry out a given function.

The term “coupled,” as used herein, is defined as “connected,” although not necessarily directly, and not necessarily mechanically.

The term “electrical power operational modes of the AC machine” are the distinct output wattage ranges e.g., (0, 5) MW, (150, 170) MW, (170, 190) MW, (190, 210) MW, (210, 230), MW, (230, 250) MW, (250, 270) MW, (270, 290) MW, (290, 310) MW that the AC machine is capable of operating. The claimed invention is not limited to these example ranges and other ranges are within the scope of the claimed invention.

The terms “including” and “having,” as used herein, are defined as comprising (i.e., open language).

The term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

It should be understood that the steps of the methods set forth herein are not necessarily required to be performed in the order described, and the order of the steps of such methods should be understood to be merely exemplary. Likewise, additional steps may be included in such methods, and certain steps may be omitted or combined in methods consistent with various embodiments of the present device.

### Overview

Electrical power engineers use Electromagnetic Interference (EMI) signatures to monitor generators' operational status and overall condition. If portions of these EMI signatures show higher-than-normal EMI energy levels, the presence of potential failure mechanisms due to electrical defects can be inferred. EMI analysis is a relatively new technology in the industry. Currently, there is no existing method to quantitatively identify the normality of EMI signatures in generators. Furthermore, each generator has a unique signature, which challenges engineers when trying to identify abnormalities, as there is no universal normality baseline.

One aspect of the present invention provides a method to use historical generator EMI signature data and their corresponding generator operational modes (out-of-service and active power output) to generate a baseline library for each generator in the fleet. In this library, each baseline signature is the statistical leverage of all the historical EMI signatures when the generator outputs a certain amount of active power and when the generator is out-of-service. A normality zone associated with each baseline is also provided using the statistical distribution of each data point on the signature curve. So that engineers can use the most suitable baseline when identifying abnormality given certain generator output. The correspondence between EMI signature patterns and generator operational modes is also proved and demonstrated using real-world data.

The claimed invention will be deployed to a cloud server where EMI signatures will be collected from generation sites and measurement devices. The operational mode data may also be collected from other data management systems, such as AVEVA PI System (formerly OSISoft PI System), widely used in the utility industry. The collected historical EMI signatures and their corresponding operational modes data will be used to establish a baseline library for each generator. Further, these libraries will be provided to the engineering and operational support services as a reference when they check for generator electrical defects. As time goes by, each library will be recalculated or recalibrated based on the most recent data to maintain its effectiveness.

The main improvements include:
1. The baseline library provides the most suitable baselines based on generator operational modes. This vastly reduces false alarms created by generator starting up or ramping down processes.
2. The correspondence between generator EMI signature patterns and its operational modes is discovered using a data-driven method in this effort.
3. An EMI signature smoothing technique is proposed in this solution for better human readability.
4. The normality zone associated with each baseline allows electric generation engineers to conduct a more comprehensive abnormality analysis and locate the troublesome equipment parts based on frequency bands with higher-than-normal EMI energy.

Insulation, conductive, and mechanical-related defects generate electromagnetic signals that can be measured via radio frequency current transformers installed in the field. Electrical defects such as partial discharges, arcing, and corona have unique patterns that can be identified in the time domain. Certain frequency bands within the spectrum can be related to specific internal components of the equipment under test.

### Power Grid Distributed System

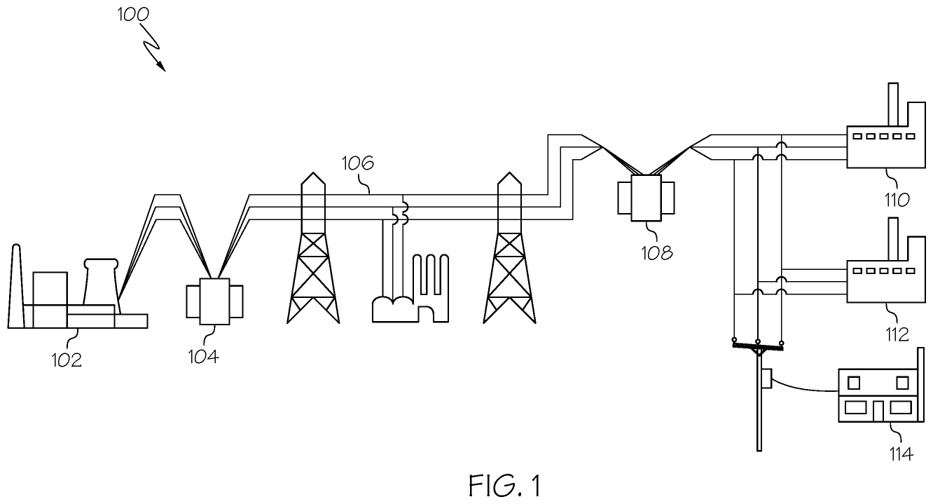

Turning now to FIG. 1 illustrates a high-level example of a power grid distributed system 100, according to the prior art. The distributed power grid 100 typically includes electricity generation plants 102, such as natural gas-powered plants, nuclear-powered plants, solar electric farms, and wind farms. These electricity generation plants 102 are electrically coupled with a step-up transformer 104. The step-up transformer 104 increases the voltage from primary to secondary. Electricity is transmitted at a high voltage on transmission lines 106 to increase efficiency. Common high voltages are 765 kV, 500 KV, 345 kV, 230 kV and 138 kV. The lower current that accompanies high-voltage transmission reduces resistance in the conductors as electricity flows along the cables. This means that thin, lightweight wires for transmission lines 106 are used in long-distance transmission.

The transmission lines 106 are electrically connected to a step-down transformer 110. The step-down transformer decreases the voltage from primary to secondary to be used by typical 26 kV and 69 kV sub-station customer 112, a 13 kV and 4 kV customer 114, and a 120 v and 240 V customer 116, as shown.

AC Machine with Radio Frequency Current Transformer

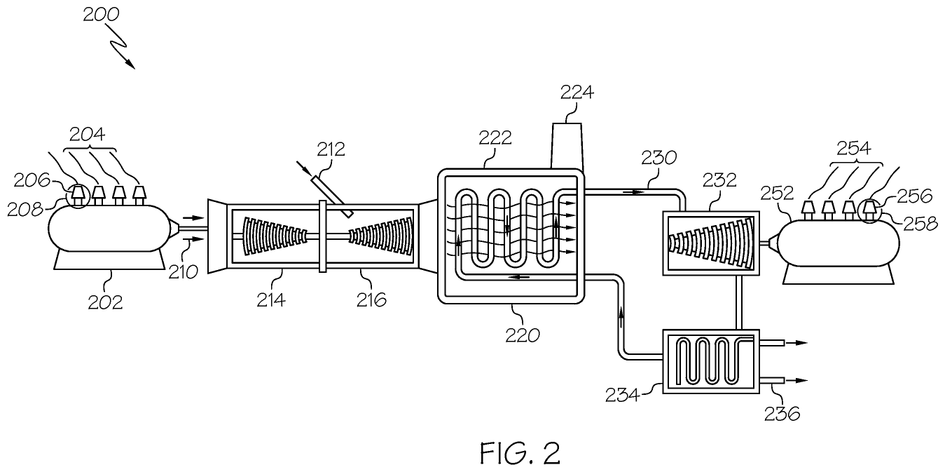

Turning to FIG. 2, illustrated is a high-level example of an electrical steam-powered generator 200 using newer natural gas combined-cycle technology with a radio frequency current transformer is shown. In this example, there are two AC generators shown 202, 252. Each AC generator is three-phase 204, 254 and includes a neutral 206, 256 with a radio frequency current transformer coupled to it 206, 256. In another example, the radio frequency current transformer is coupled to ground (not shown) for one or both of the two AC generators shown 202, 252. The natural-gas-fired combined-cycle technology produces electricity from two sources of energy instead of one. The combined cycle is about 30 percent more efficient than a traditional steam plant. Energy is produced by the combustion of natural gas in a compressor 214 with air 210, which turns a turbine 216 as shown. This is similar to a jet engine. Energy is also produced by making use of the jet engine exhaust 222 to make steam in a heat recovery unit 220 with venting stack 224. Both sources of energy then drive gas turbine 216, steam turbine 232, and electric generators 202, 252 to produce electricity. After driving the steam turbine 232, the steam is cooled with liquid, such as water 236, in a condensing unit 234 and returned to a heat recovery unit 220, as shown.

### High-Level Flow

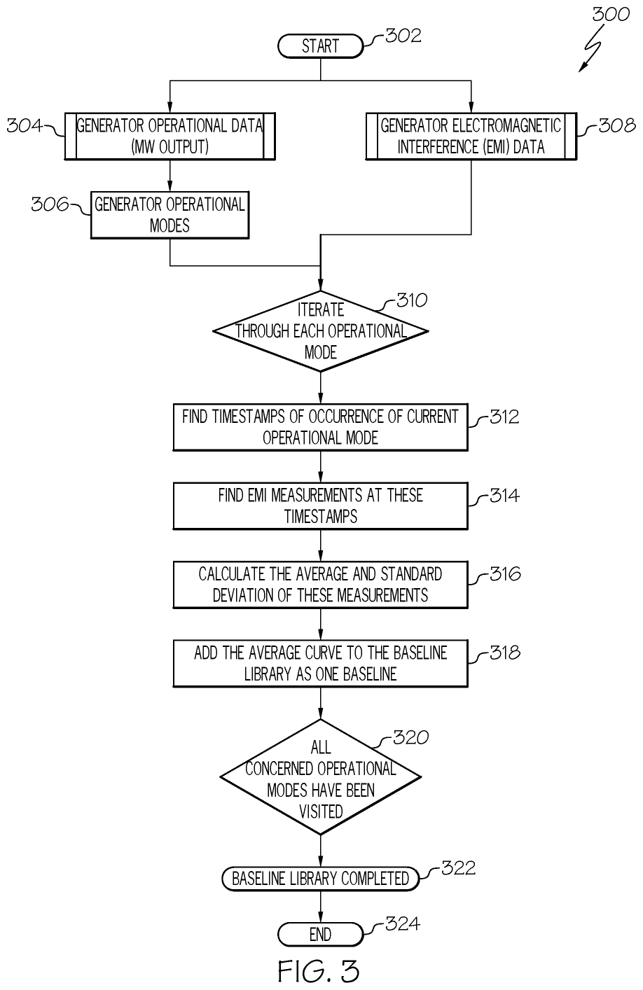

FIG. 3 is a high-level flow chart 300 of the overall process, according to an example. The process starts in step 302 and immediately proceeds to two steps 304 and 306 in parallel, as shown. In step 304, the generator operation data, such as electrical power operational modes, is retrieved. Generator output is typically measured in watts (W) or megawatts (MW). The process continues to step 306, in which each of the electrical power and a plurality of operational modes are prepared to be iterated. In parallel, the generator electromagnetic interference (EMI) data from the radio frequency current transformer coupled to the generator is captured with associated timestamps. The process flows into step 310.

In step 310, an iteration of each of the operational modes is performed through steps 312 to 320, as shown. In step 312, the timestamps of operational mode are matched with the timestamps of EMI data in step 314. The process continues to step 316.

In step 316, the system performs two statistical calculations. More specifically, the statistical average and standard deviation or other statistical deviation of these EMI data measurements are calculated. The process continues to step 318, in which the average curve is stored as one of the baselines. The process continues to step 320.

In step 320, a test is made to determine if there are more operational modes to run. In the case that more operational modes can be run, the process loops back to step 310. Otherwise, in the case that there are no more operational modes to run, the process continues to step 322 to complete the baseline library being formed. The process ends in step 324.

### Base Line Graph Versus Abnormality Graph Over Various Operational Modes

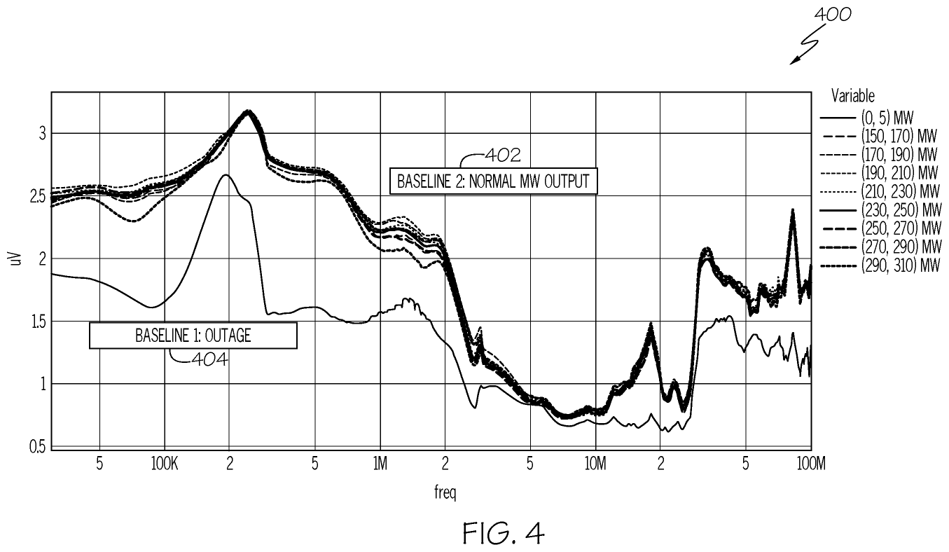

FIG. 4 is graph 400 illustrating the baseline EMI signature data at various electrical power operating modes of the AC machine. In all these graphs, the y-axis is micro-volts (uV) and the x-axis is frequency measured in Hertz (Hz). Shown is a baseline EMI signature data 402 across the various operational modes that the generator is capable of producing. In this example, the operating modes are (0, 5) MW, (150, 170) MW, (170, 190) MW, (190, 210) MW, (210, 230), MW, (230, 250) MW, (250, 270) MW, (270, 290) MW, (290, 310) MW that the AC machine is capable of operating. Note that the operating modes of (0, 5) MW appear not to correspond to the other operational modes because this baseline is for the AC machine being a mode outage, such as a scheduled outage. The claimed invention is not limited to these example ranges, and other ranges are within the scope of the claimed invention. In comparison, the outage average baseline is 404.

### Normality Zone for a Generator at One Operational Mode

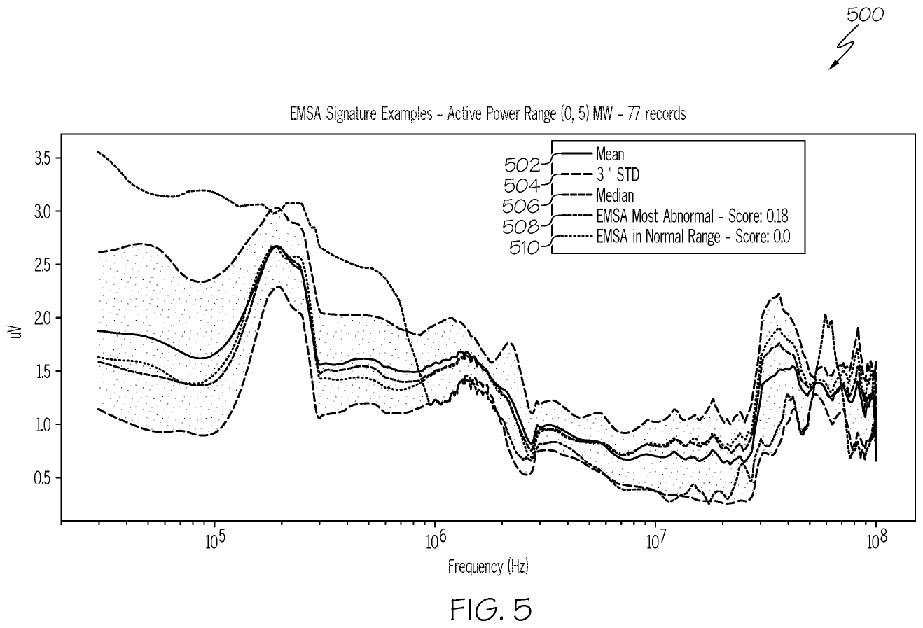

FIG. 5 is a graph 500 illustrating the application of the baseline library acquired from FIG. 3 to real-time EMI signature from one device, evaluating its abnormality score using normality zone as a part of the baseline associated with the same operation modes with the real-time data. More specifically shown is the electromagnetic signature data baseline at a given operational mode of (0.5) MW with 77 records. Shown are various statistical calculations, including the calculated mean 502, the standard deviation with 3 sigma (σ) confidence level to define a proposed normality zone 504, the median 506, the most abnormal score, i.e., a score that deviated most from the normal range 508, and a normal range score 510.

### Experimental Data for a Burnt Generator Conductor

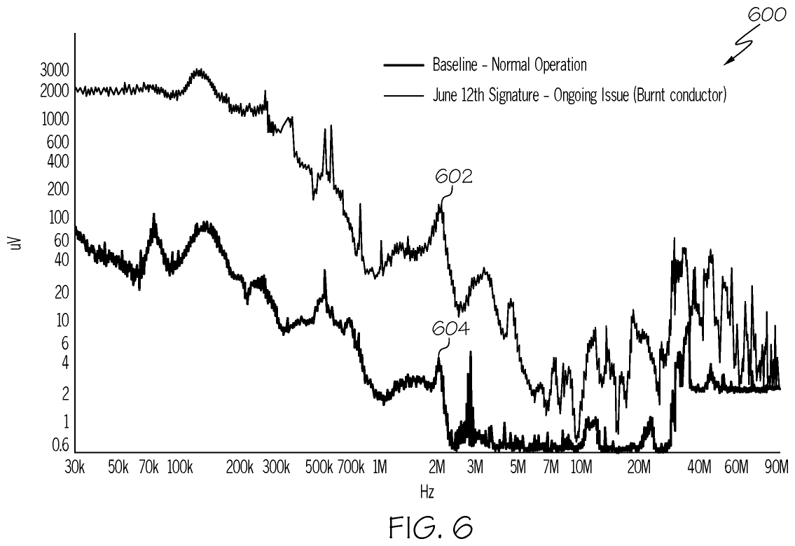

Turning now to FIG. 6, shown is a graph illustrating, with one of the signatures capture during normal operation as the baseline and a second of signatures captured during an abnormality. More specifically shown is the baseline EMI signature data at a single operating mode of the AC machine 602 before a burnt insulation jacket of a conductor. Recent EMI signature data 604 with a burnt insulation jacket of the conductor as shown.

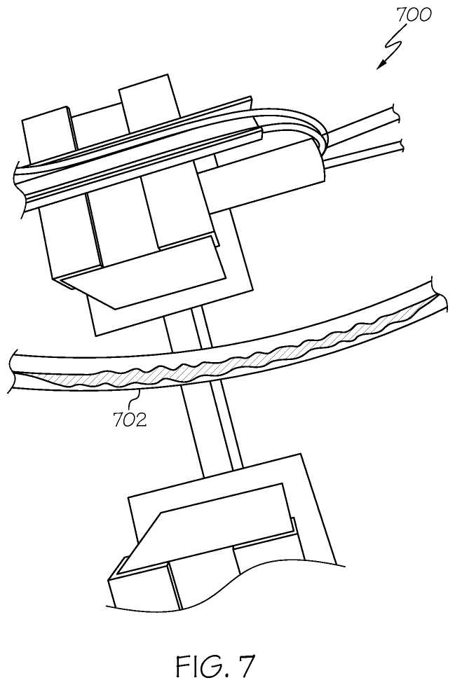

FIG. 7 is an image taken of the AC machine with the burnt insulation jacket of the conductor for the EMI signature data 604 in FIG. 6. It is important to note that the primary focus of the presently claimed invention is finding abnormalities in AC machines, such as generators. However, there are “associated devices” with the AC machine, including potential transformers and generator step-up transformers. In one example, if an abnormality is found with respect to the potential transformers and generator step-up transformers data, it is used to check if there is anything wrong with the generator. If the generator is operating normally, then the attention would be shifted to these associated devices.

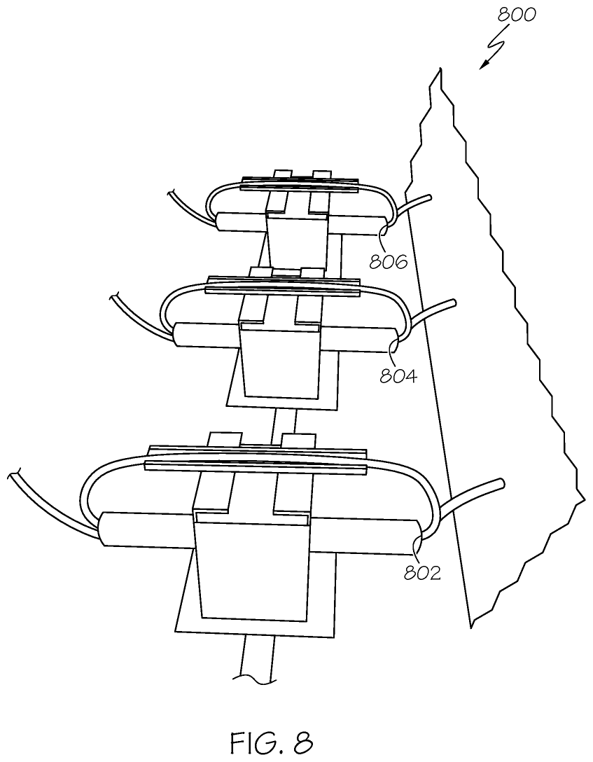

FIG. 8 is an image taken of the AC machine after the EMI signature data after a burnt insulation jacket of conductor 604 of FIG. 6 is replaced. Shown are three conductors with normal insulation jackets 802, 804, 806.

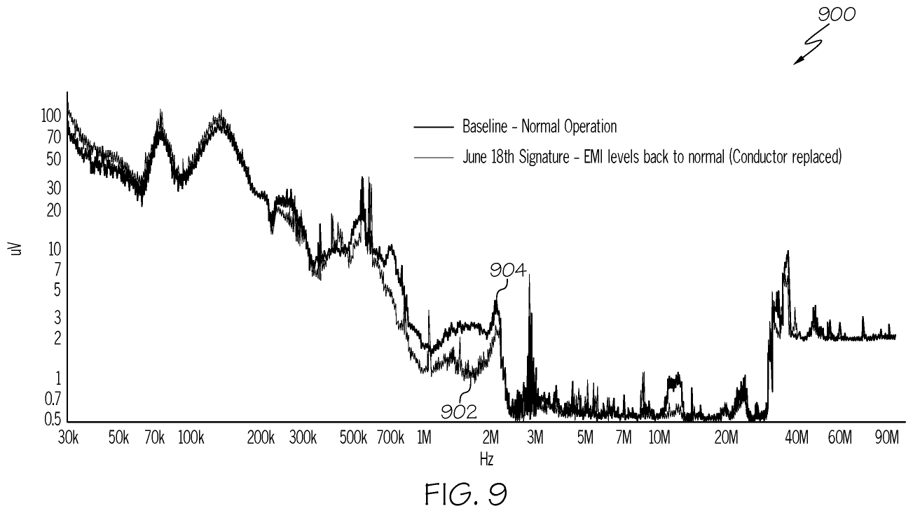

FIG. 9 is a graph illustrating the EMI signature data of a normal operation of FIG. 8 after the burnt conductor is replaced at one operating mode of the AC machine 902 after a burnt conductor insulation jacket is replaced. Recently measured EMI signature data 904 of the AC machine is tracking the historic EMI signature data 902 from the library, as shown.

### EMI Signature Data Example and Overview of Abnormality Scores

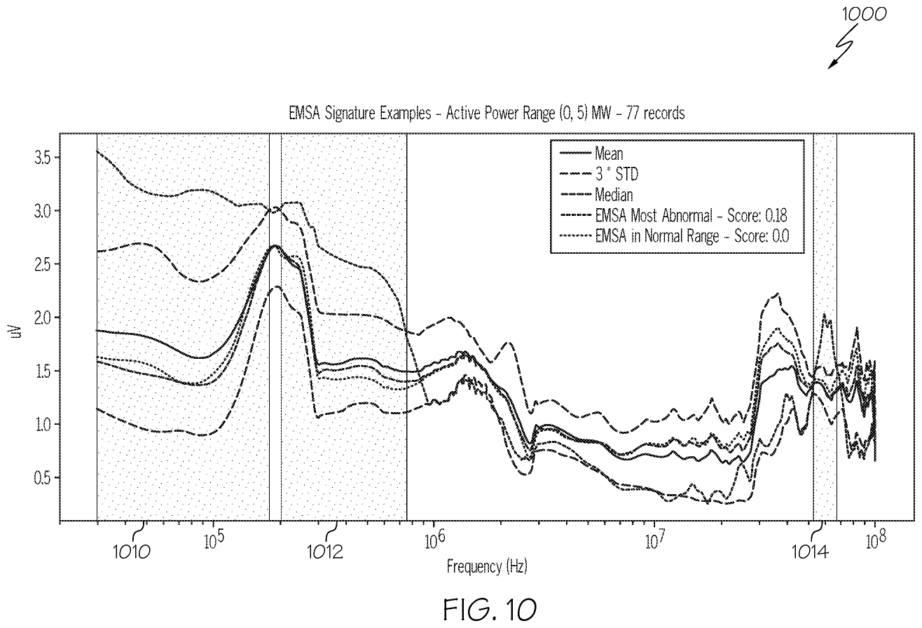

FIG. 10 is a graph 1000 illustrating the baseline at a given operational mode of (0.5) MW with 77 records. Shown are various statistical calculations, including the calculated mean, the standard deviation with a 3 sigma (σ) confidence level, the median, the most abnormal score, i.e., a score that deviated most from the normal range, and a normal range score. Also shown is an example of EMI data outside the normality zone 1010, 1012, 1014 based on the EMI signature data abnormality score of 0.18 versus a normal score of 0.0. The criticality can be accessed with further evaluation, e.g., by identifying frequency bands outside the normality zone. Time domain (zero spans) analysis is also used to recognize defects and their severity.

The normality score can be calculated automatically by the system using two different data sets. The first data set is based on using the same AC machine. The second data set uses different AC machines, typically from the same model family.

At a high level, the Abnormality Score is a ratio of i) the area of the standard deviation with 3 sigma (σ) confidence level and ii) the sum of three areas 1010, 1012, 1014 exceeding the standard deviation curve.

The abnormality score for the same machine is calculated based on a ratio between i) an area of the normality zone defined by the standard deviation for the historic set of EMI data associated with the operational mode of the recent EMI data over the series of time intervals and ii) a sum of areas of the recent EMI data that is above the upper limit; and classifying level of the abnormality using the abnormality score.

### EMI Signature Data Example and Overview of Abnormality Scores

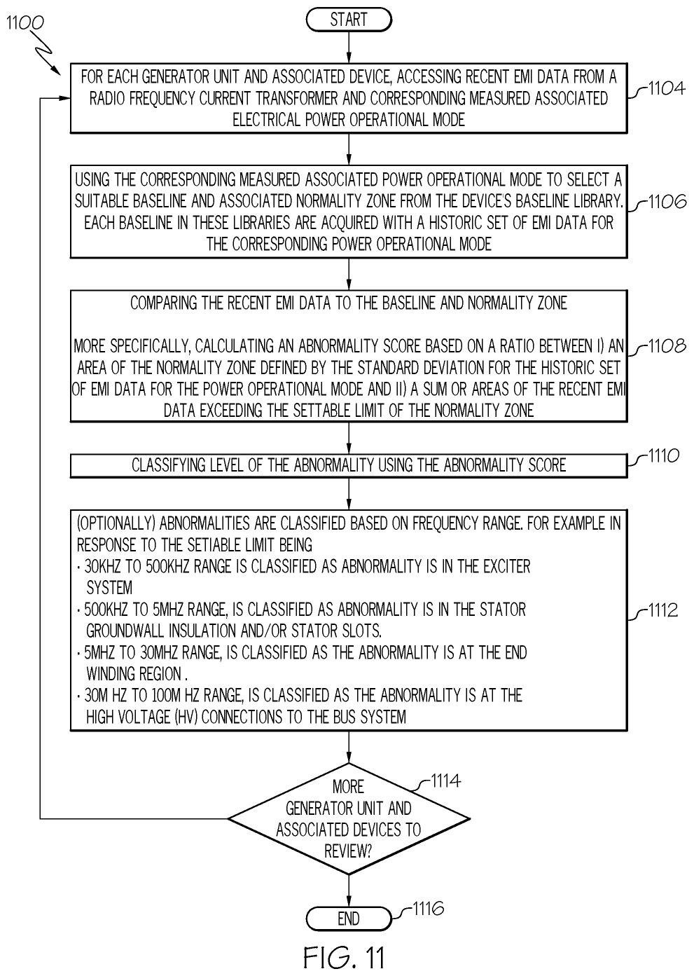

FIG. 11 is a flow chart 1100 of identifying an abnormality using historical baseline and normality zone against recent EMI signature data. The process begins in step 1102 and immediately proceeds to step 1104. In step 1104, for each generator unit and associated device, the process flow accesses recent EMI data from a radio frequency current transformer from the AC machine and the corresponding measured associated electrical power operational mode. As noted above, with reference to the description for FIG. 4, the term “associated devices” with the AC machine includes potential transformers and generator step-up transformers. In one example, if an abnormality is found with respect to the potential transformers and generator step-up transformers data, it is used to check if there is anything wrong with the generator. If the generator is operating normally, then the attention would be shifted to these associated devices. The process continues to step 1106.

In step 1106, the corresponding measured associated power operational mode is used as a key or index to select a suitable baseline and associated normality zone from the AC machine's baseline data from the baseline library. Each baseline in these libraries is acquired with a historic set of EMI data for the corresponding power operational mode. The process continues to step 1108.

In step 1108, the recent EMI data is compared to the baseline data from the baseline library and normality zone. More specifically, an abnormality score is calculated based on a ratio between i) an area of the normality zone defined by the standard deviation for the historic set of EMI data and power data over the series of time intervals and ii) a sum of areas of the recent set of EMI data and power data that is above the upper limit of the normality zone. The process continues to step 1110.

In step 1110, the process flow classifies a level of the abnormality using an abnormality score.

In one example, this information is presented to the user on a graphical on a real-time basis, as shown in FIG. 10. However, to make the information easier to understand, various colors, shading, and other emphasis may be used. The process continues to an optional step 1112.

In optional step 1112, the types of abnormalities are classified based on the frequency range. The repair procedure for the AC machine may be selected automatically from one of a plurality of repair procedures based on the frequency range of the abnormality. For example, wherein the repair procedure is an exciter system of the AC machine based on the settable limit being exceeded in a 30 kHz to 500 kHz range. The repair procedure is a stator groundwall insulation and/or stator slots of the AC machine based on the settable limit being exceeded in a 500 kHz to 5 MHz range. The repair procedure is an end winding region of the AC machine on the settable limit being exceeded in a 5 MHz to 30 MHz range. The repair procedure is a high voltage (HV) connection to a bus system of the AC machine based on the settable limit being exceeded in a 30 MHz to 100 MHz range. The process continues to step 1114.

In step 1114, a test is made to determine if additional AC machines or generators and associated devices are to be monitored. In response to additional AC machines and associated devices are to be monitored, the process returns to step 1104, as shown. Otherwise, the process ends in step 1116.

### Information Processing System

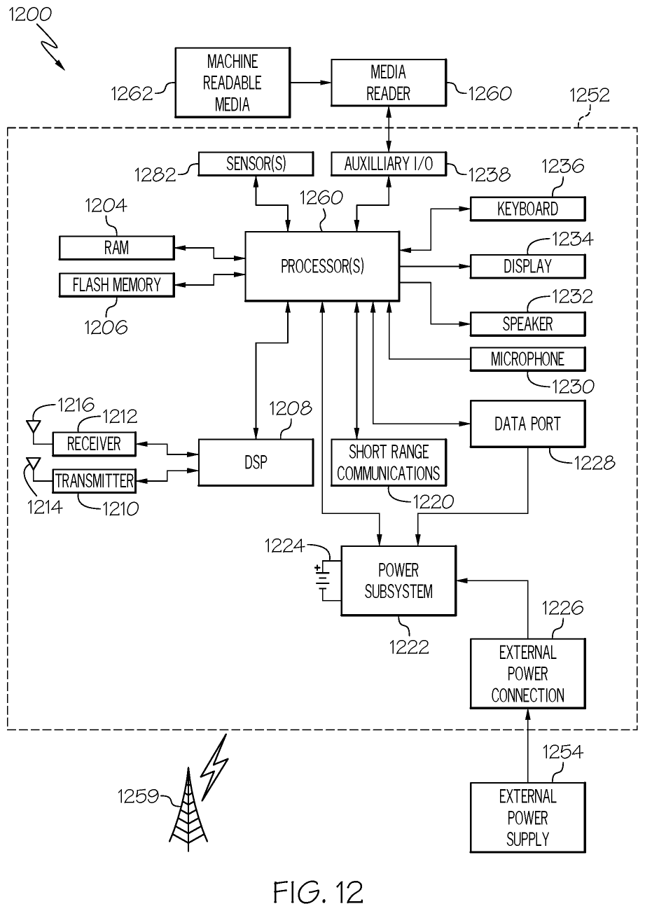

FIG. 12 is a block diagram of an example of an electronic device, such as a computer, including laptop computer or other portable device, such as a smartphone, that may run the software to carry out the flow chart of FIG. 3 and FIG. 10 above and to provide the graphs shown running analysis software. The computer may communicates over a wired or wireless network to one or more radio frequency current transformers coupled too one of a ground or a neutral line of an AC machine. The system may incorporate communication subsystem elements such as a wireless transmitter 1210, a wireless receiver 1212, and associated components such as one or more antenna elements 1214 and 1216. A digital signal processor (DSP) 1208 performs processing to extract data from received wireless signals and to generate signals to be transmitted. The particular design of the communication subsystem is dependent upon the communication network and associated wireless communications protocols with which the device is intended to operate.

The electronic device 1200 includes a microprocessor 1202 that controls the overall operation of the electronic device 1252. The microprocessor 1202 interacts with the above-described communications subsystem elements and also interacts with other device subsystems such as non-volatile or flash memory 1206, random access memory (RAM) 1204, auxiliary input/output (I/O) device 1238, data port 1228, display 1234, keyboard 1236, speaker 1232, microphone 1230, a short-range communications subsystem 1220, a power subsystem 1222, and or any other device subsystems.

One or more sensors 1282 such as radio frequency current transformed discussed above are communicative coupled with the device 1200. Such devices or technology enable the conversion of EM information to an electric signal that is interpreted by microprocessor 1202.

A battery 1224 is connected to a power subsystem 1222 to provide power to the circuits of the electronic device 1252. The power subsystem 1222 includes power distribution circuitry for providing power to the electronic device 1200 and also contains battery charging circuitry to manage recharging the battery 1224. The power subsystem 1222 includes a battery monitoring circuit that is operable to provide status of one or more battery status indicators, such as remaining capacity, temperature, voltage, electrical current consumption, and the like, to various components of the electronic handheld 1200. There may be an external power connector 1226 electrically coupled to an external power supply 1254 as shown.

The data port 1228 is able to support data communications between the electronic device 1200 and other devices through various modes of data communications, such as high speed data transfers over optical communications circuits or over electrical data communications circuits such as a USB connection incorporated into the data port 1228 of some examples. Data port 1228 is able to support communications with, for example, an external computer or other device.

Data communication through data port 1228 enables a user to set preferences through the external device or through a software application and extends the capabilities of the device by enabling information or software exchange through direct connections between the electronic device 1252 and external data sources rather than via a wireless data communication network 1259. In addition to data communication, the data port 1228 provides power to the power subsystem 1222 to charge the battery 1224 or to supply power to the electronic circuits, such as microprocessor 1202, of the electronic device 1200.

Operating system software used by the microprocessor 1202 is stored in flash memory 1206. Further examples are able to use a battery backed-up RAM or other non-volatile storage data elements to store operating systems, other executable programs, or both. The operating system software, device application software, or parts thereof, are able to be temporarily loaded into volatile data storage such as RAM 1204. One example of data storage in RAM is time and expense environment 250. Data received via wireless communication signals or through wired communications are also able to be stored to RAM 1204.

The microprocessor 1202, in addition to its operating system functions, is able to execute software applications on the electronic device 1200. A predetermined set of applications that control basic device operations.

Further applications may also be loaded onto the electronic device 1200 through, for example, the wireless network 1250, an auxiliary I/O device 1238, data port 1228, short-range communications subsystem 1220, or any combination of these interfaces. Such applications are then able to be installed by a user in the RAM 1204 or a non-volatile store for execution by the microprocessor 1202.

In a data communication mode, a received signal such as a text message or web page download is processed by the communication subsystem, including wireless receiver 1212 and wireless transmitter 1210, and communicated data is provided the microprocessor 1202, which is able to further process the received data for output to the display 1234, or alternatively, to an auxiliary I/O device 1238 or the data port 1228. A user of the electronic device 1252 may also compose data items, such as email messages, using the keyboard 1236, which is able to include a complete alphanumeric keyboard or a telephone-type keypad, in conjunction with the display 1234 and possibly an auxiliary I/O device 1238. Such composed items are then able to be transmitted over a communication network through the communication subsystem.

For voice communications, overall operation of the electronic device 1200 is substantially similar, except that received signals are generally provided to a speaker 1232 and signals for transmission are generally produced by a microphone 1230. Alternative voice or audio I/O subsystems, such as a voice message recording subsystem, may also be implemented on the electronic device 1200. Although voice or audio signal output is generally accomplished primarily through the speaker 1232, the display 1234 may also be used to provide an indication of the identity of a calling party, the duration of a voice call, or other voice call related information, for example.

Depending on the conditions or statuses of the electronic device 1200, one or more particular functions associated with a subsystem circuit may be disabled, or an entire subsystem circuit may be disabled. For example, if the battery temperature is low, then voice functions may be disabled, but data communications, such as email, may still be enabled over the communication subsystem.

A short-range communications subsystem 1220 provides for data communication between the electronic device 1252 and different systems or devices, which need not necessarily be similar devices. For example, the short-range communications subsystem 1220 includes an infrared device and associated circuits and components or a Radio Frequency based communication module such as one supporting Bluetooth® communications, to provide for communication with similarly-enabled systems and devices, including the data file transfer communications described above.

A media reader 1260 is able to be connected to an auxiliary I/O device 1238 to allow, for example, loading computer readable program code of a computer program product into the electronic device 1200 for storage into non-volatile memory such as flash memory 1206. One example of a media reader 1260 is an optical drive such as a CD/DVD drive, which may be used to store data to and read data from a computer readable medium or storage product such as computer readable storage media 1262. Examples of suitable computer readable storage media include optical storage media such as a CD or DVD, magnetic media, or any other suitable data storage device. Media reader 1260 is alternatively able to be connected to the electronic device through the data port 1228 or computer readable program code is alternatively able to be provided to the electronic device 1200 through the wireless network 1250.

### Non-Limiting Examples

Although specific examples of the subject matter have been disclosed, those having ordinary skill in the art will understand that changes can be made to the specific examples without departing from the spirit and scope of the disclosed subject matter. The scope of the disclosure is not to be restricted, therefore, to the specific examples, and it is intended that the appended claims cover any and all such applications, modifications, and examples within the scope of the present disclosure.

What is claimed is:

1. A computer-implemented method for detecting an abnormality on an alternating current (AC) machine, the method comprising:
coupling at least one radio frequency current transformer to one of a ground or a neutral line of an AC machine;
iteratively performing through a series of electrical power operational modes of the AC machine, each of
receiving a measurement of electromagnetic interference (EMI) data from the at least one radio frequency current transformer over a series of time intervals;
receiving a measurement of power data from the AC machine over the series of time intervals to produce a historic set of EMI data and power data over the series of time intervals;
identifying the power data associated with each EMI signature data;
using this power data to cluster the EMI signature data;
for each EMI signature data cluster, calculate a mean value and statistical deviation value;
storing over the series of time intervals each of i) the historic set of EMI data and power information data, ii) the mean value, and iii) the statistical deviation value, thereby establishing the AC machine's baseline data in a baseline library for normal operations.

2. The computer-implemented method of claim 1, further comprising:
for each generator unit and associated device,
accessing recent EMI data from a radio frequency current transformer from the AC machine and corresponding measured associated electrical power operational mode;
using the corresponding measured associated power operational mode to select a suitable baseline and associated normality zone from the AC machine's baseline data from the baseline library, each baseline in these libraries are acquired with a historic set of EMI data for the corresponding power operational mode;
comparing the recent EMI data to the baseline data from the baseline library and normality zone; and
classifying level of the abnormality using an abnormality score.

3. The computer-implemented method of claim 2, further comprising:
calculating an abnormality score based a ratio between i) an area of the normality zone defined by the statistical deviation for the historic set of EMI data and power data over the series of time intervals and ii) a sum or areas of the recent set of EMI data and power data that is above a settable upper limit of the normality zone; and
classifying level of the abnormality using the abnormality score.

4. The computer-implemented method of claim 3, further comprising:
in response to the settable upper limit being exceeded in a 30 kHz to 500 kHz range, sending a notification that the abnormality is at an exciter system of a generator;
in response to the settable upper limit being exceeded in a 500 kHz to 5 MHz range, sending a notification that the abnormality is at a stator groundwall insulation and/or stator slots of a generator;
in response to the settable upper limit being exceeded in a 5 MHz to 30 MHz range, sending a notification that the abnormality is at an end winding region of a generator; and
in response to the settable upper limit being exceeded in a 30 MHz to 100 MHz range, sending a notification that the abnormality is at a high voltage connection to a bus system of a generator.

5. The computer-implemented method of claim 1, further comprising:
for each generator unit and associated device,
accessing recent EMI data from a radio frequency current transformer from a different AC machine and corresponding measured associated electrical power operational mode;
using the corresponding measured associated power operational mode to select a suitable baseline and associated normality zone from the AC machine's baseline data from the baseline library, each baseline in these libraries are acquired with a historic set of EMI data for the corresponding power operational mode;
comparing the recent EMI data from the different AC machine to the baseline data from the baseline library and normality zone; and
classifying level of the abnormality using an abnormality score.

6. The computer-implemented method of claim 4, further comprising:
selecting one of a plurality of repair procedures based on the frequency range of the abnormality, wherein the repair procedure is
an exciter system of the AC machine based on the settable limit being exceeded in a 30 kHz to 500 kHz range;
a stator groundwall insulation and/or stator slots of the AC machine based on the settable limit being exceeded in a 500 kHz to 5 MHz range;
an end winding region of the AC machine based on the settable limit being exceeded in a 5 MHz to 30 MHz range; and
a high voltage (HV) connection to a bus system of the AC machine based on the settable limit being exceeded in a 30 MHz to 100 MHz range.

7. The computer-implemented method of claim 1, wherein the electrical power operational modes are measured in watts output.

8. The computer-implemented method of claim 1, wherein the alternating current (AC) machine is one of a generator and a transformer.

9. The computer-implemented method of claim 1, wherein the EMI data is measured in micro Volts and hertz, and power information data is measured in watts.

10. The computer-implemented method of claim 1, further comprising:
displaying on a two-axis graph for one or more of the electrical power operational modes over a series of time intervals, each of i) the set of EMI data and power information data, ii) the mean value, and iii) the statistical deviation.

11. The computer-implemented method of claim 10, wherein each of the electrical power operational modes is displayed in different colors, a y-axis is watts, an x-axis is frequency, and the statistical deviation is displayed as a shaded region.

12. A system for detecting an abnormality on an alternating current (AC) machine, the system comprising
memory;
at least one processor;
a radio frequency current transformer coupled to one of a ground or a neutral line of an AC machine;
a software manager operatively coupled to the memory and the at least one processor, wherein the software manager performs:
iteratively performing through a series of electrical power operational modes of the AC machine, each of
receiving a measurement of electromagnetic interference (EMI) data from the radio frequency current transformer over a series of time intervals;
receiving a measurement of power data from the AC machine over the series of time intervals to produce a historic set of EMI data and power data over the series of time intervals;
identifying the power data associated with each EMI signature data;
using this power data to cluster the EMI signature data;
for each EMI signature data cluster, calculate a mean value and statistical deviation value;
storing over the series of time intervals each of i) the historic set of EMI data and power information data, ii) the mean value, and iii) the statistical deviation value, thereby establishing the AC machine baseline data in a baseline library for normal operations.

13. The system of claim 12, further comprising:
for each generator unit and associated device,
accessing recent EMI data from a radio frequency current transformer from the AC machine and corresponding measured associated electrical power operational mode;
using the corresponding measured associated power operational mode to select a suitable baseline and associated normality zone from the AC machine's baseline data from the baseline library, each baseline in these libraries are acquired with a historic set of EMI data for the corresponding power operational mode;
comparing the recent EMI data to the baseline data from the baseline library and normality zone; and
classifying level of the abnormality using an abnormality score.

14. The system of claim 13, further comprising:
calculating an abnormality score based a ratio between i) an area of the normality zone defined by the statistical deviation value for the historic set of EMI data and power data over the series of time intervals and ii) a sum or areas of the recent set of EMI data and power data that is above a settable upper limit; and
classifying level of the abnormality using the abnormality score.

15. The system of claim 14, further comprising:
selecting one of a plurality of repair procedures based on the frequency range of the abnormality, wherein the repair procedure is
an exciter system of the AC machine based on the settable limit being exceeded in a 30 kHz to 500 kHz range;
a stator groundwall insulation and/or stator slots of the AC machine based on the settable limit being exceeded in a 500 kHz to 5 MHz range;
an end winding region of the AC machine based on the settable limit being exceeded in a 5 MHz to 30 MHz range; and
a high voltage (HV) connection to a bus system of the AC machine based on the settable limit being exceeded in a 30 MHz to 100 MHz range.

16. The system of claim 12, further comprising:
for each generator unit and associated device,
accessing recent EMI data from a radio frequency current transformer from the AC machine and corresponding measured associated electrical power operational mode;
using the corresponding measured associated power operational mode to select a suitable baseline and associated normality zone from the AC machine's baseline data from the baseline library, each baseline in these libraries are acquired with a historic set of EMI data for the corresponding power operational mode;
comparing the recent EMI data to the baseline data from the baseline library and normality zone; and
classifying level of the abnormality using an abnormality score.

17. The system of claim 15, further comprising:
in response to the settable limit being exceeded in a 30 kHz to 500 kHz range, sending a notification that the abnormality is at the exciter system of a generator;
in response to the settable limit being exceeded in a 500 kHz to 5 MHz range, sending a notification that the abnormality is at the stator groundwall insulation and/or stator slots of a generator;
in response to the settable limit being exceeded in a 5 MHz to 30 MHz range, sending a notification that the abnormality is at the end winding region of a generator; and
in response to the settable limit being exceeded in a 30 MHz to 100 MHz range, sending a notification that the abnormality is at the high voltage (HV) connections to the bus system of a generator.

18. The system of claim 12, wherein the electrical power operational modes are measured in watts output.

19. The system of claim 12, wherein the alternating current (AC) machine is one of a generator and a transformer.

20. The system of claim 12, wherein the EMI data is measured in micro Volts and hertz, and power information data is measured in watts.
